(19) United States
(12) Patent Application Publication
(10) Pub. No.: US 2024/0304708 A1
(43) Pub. Date: Sep. 12, 2024

(54) INSULATED GATE BIPOLAR TRANSISTOR AND METHOD OF MANUFACTURING SAME

(71) Applicant: DB HiTek Co., Ltd., Bucheon-si (KR)

(72) Inventor: Ji Sun KIM, Yongin-si (KR)

(21) Appl. No.: 18/326,077

(22) Filed: May 31, 2023

(30) Foreign Application Priority Data
Mar. 8, 2023 (KR) 10 2023 0030305

(51) Int. Cl. H01L 29/739; H01L 29/10; H01L 29/66

(52) U.S. Cl. CPC H01L 29/7397; H01L 29/1095; H01L 29/66348

(57) ABSTRACT

Disclosed are an insulated gate bipolar transistor and a method of manufacturing the same. More particularly, an insulated gate bipolar transistor and a method of manufacturing the same include a planar gate on a drift region or a first body region in a floating region of the insulated gate bipolar transistor, and if desired or necessary, a second trench gate in the first body region to increase an input capacitance (Cies) and prevent self-turn-on of the insulated gate bipolar transistor.

### CROSS REFERENCE TO RELATED APPLICATION

The present application claims priority to Korean Patent Application No. 10-2023-0030305, filed Mar. 8, 2023, the entire contents of which are incorporated herein for all purposes by this reference.

### BACKGROUND OF THE INVENTION

### Field of the Invention

The present disclosure relates generally to an insulated gate bipolar transistor and a method of manufacturing the same. More particularly, the present disclosure relates to an insulated gate bipolar transistor and a method of manufacturing the same, including a planar gate on a drift region or a first body region in a floating region (e.g., of the insulated gate bipolar transistor), and if desired or necessary, a second trench gate is additionally formed in the first body region to prevent self-turn-on by increasing an input capacitance (Cies).

### Description of the Related Art

An insulated gate bipolar transistor (IGBT) is an ideal switching device that combines the characteristics of an insulated gate structure of a MOS transistor and the high current density of a bipolar transistor. In detail, the insulated gate bipolar transistor has an advantage of bipolar operation, which can significantly reduce on-resistance by conductivity modulation.

FIG. 1 is a cross-sectional view illustrating an insulated gate bipolar transistor 9 according to the related art.

Hereinbelow, the structure of the insulated gate bipolar transistor 9 according to the related art and the problems thereof will be described with reference to the accompanying drawings.

Referring to FIG. 1, the insulated gate bipolar transistor 9 according to the related art includes a trench gate 910 at the boundary between a floating region B1 and an active region B2. In addition, a first conductivity type body region 930 is between a pair of adjacent trench gates 910. In general, when the insulated gate bipolar transistor 9 is implemented in an inverter, a pair of transistors 9 are designed to have different gate on/off times. In contrast, when the pair of transistors 9 are turned on simultaneously, there is a possibility that the devices may be damaged as a result of a short circuit.

In this case, if the input capacitance (Cies) of the transistors 9 is small, a “self-turn-on” may occur in the devices due to gate noise. Thus, a large input capacitance (Cies) is advantageous in preventing self-turn-on. Here, the input capacitance (Cies) may be defined as the sum of a gate to collector parasitic capacitance (Cgc) and a gate to emitter parasitic capacitance (Cge). In the related-art transistor 9, the input capacitance (Cies) may be defined as the sum of a trench gate to emitter parasitic capacitance (Cge=Cap1) and a trench gate to collector parasitic capacitance (Cgc=Cap2) (Cies=Cap1+Cap2).

Accordingly, the present inventors have conceived a novel insulated gate bipolar transistor having an improved structure to prevent self-turn-on, which will be described in detail later.

The foregoing is intended merely to aid in the understanding of the background of the present disclosure, and is not intended to mean that the present disclosure falls within the purview of the related art or information that is already known to those skilled in the art.

### DOCUMENTS OF RELATED ART

Korean Patent Application Publication No. 10-2009-0070516, entitled “Insulated gate bipolar transistor and method for manufacturing the same.”

### SUMMARY OF THE INVENTION

Accordingly, the present disclosure has been made keeping in mind the above problems occurring in the related art, and an objective of the present disclosure is to provide an insulated gate bipolar transistor and a method of manufacturing the same, including a planar gate on a first body region in a floating region (e.g., of the insulated gate bipolar transistor) to prevent self-turn-on by increasing an input capacitance (Cies) of the insulated gate bipolar transistor.

Another objective of the present disclosure is to provide an insulated gate bipolar transistor and a method of manufacturing the same, including a second trench gate below the planar gate in addition to a first trench gate to prevent self-turn-on by further increasing the input capacitance (Cies) of the insulated gate bipolar transistor.

Another objective of the present disclosure is to provide an insulated gate bipolar transistor and a method of manufacturing the same, including a second trench gate at a shallower depth in a drift region (e.g., of the insulated gate bipolar transistor) than the first trench gate to increase the input capacitance (Cies) of the insulated gate bipolar transistor while minimizing an increase in the feedback capacitance (Cres) (e.g., of the insulated gate bipolar transistor).

Another objective of the present disclosure is to provide an insulated gate bipolar transistor and a method of manufacturing the same, including a planar gate and/or a second trench gate only in the floating region (e.g., of the insulated gate bipolar transistor), so that structural changes to the active region of the insulated gate bipolar transistor are not required.

Another objective of the present disclosure is to provide a method of manufacturing an insulated gate bipolar transistor, including forming a second trench gate and a first trench gate substantially simultaneously (e.g., in the same process step[s]), to maintain process efficiency.

Another objective of the present disclosure is to provide a method of manufacturing an insulated gate bipolar transistor, including forming a planar gate together with the first trench gate to prevent deterioration in process efficiency as much as possible.

In order to achieve the above objectives, according to one aspect of the present disclosure, there is provided an insulated gate bipolar transistor including a collector electrode; a collector on the collector electrode; a drift region on the collector; a plurality of first trench gates spaced apart from each other in the drift region; a first body region between first adjacent ones of the first trench gates and in the drift region (e.g., at an uppermost surface thereof); a second body region between second adjacent ones of the first trench gates and in the drift region; and a planar gate between the first adjacent ones of the first trench gates and on the first body region.

According to another aspect of the present disclosure, the insulated gate bipolar transistor may further include an interlayer insulating layer covering the planar gate, the first body region and the second body region; and an emitter electrode on the interlayer insulating layer. Here, the first body region may float (e.g., may be electrically disconnected from other electrically active structures, such as a ground potential).

According to another aspect of the present disclosure, the first body region may be deeper in the drift region (e.g., have a lowermost surface farther from an uppermost surface of the drift region) than the second body region (or a lowermost surface thereof).

According to another aspect of the present disclosure, the insulated gate bipolar transistor may further include an emitter in the second body region; and a body contact in the second body region. Here, the emitter may be electrically connected to the emitter electrode.

According to another aspect of the present disclosure, the planar gate may include a gate insulating layer on the first body region; and a gate electrode on the gate insulating layer.

According to another aspect of the present disclosure, the insulated gate bipolar transistor may further include a buffer layer on the collector.

According to another aspect of the present disclosure, there is provided an insulated gate bipolar transistor including a collector electrode; a collector on the collector electrode; a drift region on the collector; a plurality of first trench gates spaced apart from each other in the drift region; a first body region between adjacent ones of the first trench gates and in the drift region (e.g., at an uppermost surface thereof); a second body region between different adjacent ones of the first trench gates and in the drift region; a planar gate between the different adjacent ones of the first trench gates and on the first body region; and a second trench gate in the first body region.

According to another aspect of the present disclosure, the second trench gate may be connected to the planar gate.

According to another aspect of the present disclosure, the second trench gate may have a lowermost surface in the first body region.

According to another aspect of the present disclosure, the second trench gate may have a shallower depth than the first trench gates.

According to another aspect of the present disclosure, the second trench gate may have a narrower width than the first trench gates.

According to another aspect of the present disclosure, the second trench gate may include a gate insulating layer on an inner wall of a trench; and a gate electrode on the gate insulating layer and filling the trench. Here, the first body region may float.

According to another aspect of the present disclosure, there is provided an insulated gate bipolar transistor including a collector electrode; a collector on the collector electrode; a drift region on the collector; a plurality of first trench gates spaced apart from each other in the drift region; a floating first body region between adjacent ones of the first trench gates and in the drift region (e.g., at an uppermost surface thereof, and/or in a floating region of the insulated gate bipolar transistor); a second body region between adjacent ones of the first trench gates and in the drift region, in an active region; a planar gate between the pair of adjacent first trench gates and on the first body region, in the floating region; and a second trench gate spaced apart from the pair of adjacent first trench gates in the first body region in the floating region, and having a lowermost surface deeper than lowermost surface of the first body region.

According to another aspect of the present disclosure, the second trench gate may have a narrower width and a smaller depth or vertical length than the first trench gates.

According to another aspect of the present disclosure, the first body region may have a lowermost surface at substantially the same depth as a lowermost surface of the second body region.

According to another aspect of the present disclosure, there is provided a method of manufacturing an insulated gate bipolar transistor, the method including forming a drift region on a collector; forming a first body region in a drift region (and, e.g., in a floating region of the insulated gate bipolar transistor); forming a plurality of first trench gates spaced apart from each other in the drift region; forming a planar gate on the first body region; forming a second body region in the drift region (and, e.g., in an active region of the insulated gate bipolar transistor); forming an emitter in the second body region; forming an interlayer insulating layer on the first body region and the second body region, covering the planar gate; and forming an emitter electrode on the interlayer insulating layer.

According to another aspect of the present disclosure, forming the plurality of first trench gates may include forming a plurality of first trenches having a first depth in the drift region; forming an insulating layer in the first trenches and on the first body region; and forming a first polysilicon layer on the insulating layer to form the first trench gates.

In some embodiments, the method of manufacturing the insulated gate bipolar transistor may further comprise forming a second trench having a second depth between adjacent ones of the first trenches and in the first body region (and, alternatively or additionally, in the floating region); forming the insulating layer in the second trench; and forming the first polysilicon layer on the insulating layer in the second trench to form a second trench gate. According to another aspect of the present disclosure, the second depth may be shallower than the first depth.

According to another aspect of the present disclosure, forming the emitter electrode on the interlayer insulating layer may include forming a contact hole in the interlayer insulating layer (and, alternatively or additionally, in the active region); forming a body contact in the second body region exposed by the contact hole; and forming a conductive layer in the contact hole and on the interlayer insulating layer.

According to another aspect of the present disclosure, the planar gate may be formed by blanket depositing a second polysilicon layer on the insulating layer and etching the second polysilicon layer.

The above configurations may provide the following effects.

According to the present disclosure, the planar gate on the first body region and/or in the floating region can increase the input capacitance (Cies) and prevent self-turn-on of the insulated gate bipolar transistor.

In addition to the first trench gates, the second trench gate below the planar gate can further increase the input capacitance (Cies) and prevent self-turn-on of the insulated gate bipolar transistor.

In addition, the second trench gate having a shallower depth in the drift region than the first trench gates can increase the input capacitance (Cies) of the insulated gate bipolar transistor while minimizing an increase in the feedback capacitance (Cres) of the insulated gate bipolar transistor.

In addition, by forming the planar gate and/or the second trench gate only in the floating region of the insulated gate bipolar transistor, structural changes to the active region of the insulated gate bipolar transistor are not made or required.

In addition, forming the second trench gate and the first trench gates substantially simultaneously (e.g., in the same process sequence and//or step[s]) can maintain or prevent any deterioration in process efficiency.

In addition, forming the planar gate together with the first trench gates in the process of forming the first trench gates can prevent deterioration in process efficiency as much as possible.

Meanwhile, the effects of the present disclosure are not limited to the above-mentioned effects, and other effects not mentioned above can be clearly understood from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating an insulated gate bipolar transistor according to the related art;

FIG. 2 is a cross-sectional view illustrating an exemplary insulated gate bipolar transistor according to a first embodiment of the present disclosure;

FIG. 3 is a cross-sectional view illustrating an exemplary insulated gate bipolar transistor according to a second embodiment of the present disclosure;

FIG. 4 is a cross-sectional view illustrating an exemplary insulated gate bipolar transistor according to a third embodiment of the present disclosure; and

FIGS. 5 to 16 are cross-sectional views illustrating structures formed during an exemplary method of manufacturing an insulated gate bipolar transistor according to the present disclosure.

### DETAILED DESCRIPTION OF THE INVENTION

Hereinafter, exemplary embodiments of the present disclosure will be described in more detail with reference to the accompanying drawings. Embodiments of the present disclosure can be modified in various forms. Therefore, the scope of the present disclosure should not be construed as being limited to the following embodiments, but should be construed on the basis of the descriptions in the appended claims. The embodiments of the present disclosure are provided for complete disclosure and to fully convey the scope of the present disclosure to those skilled in the art.

As used herein, when an element (or layer) is referred to as being on another element (or layer), it can be directly on the other element, or one or more intervening elements (or layers) may be therebetween. In contrast, when an element is referred to as being directly on or above another element, no intervening elements are therebetween. Further, the terms “on”, “above”, “below”, “upper”, “lower”, “one side”, “side surface”, etc. describe one element's relationship to another element illustrated in the drawings.

While the terms “first”, “second”, etc. may be used herein to describe various items such as various elements, regions and/or parts, these items should not be limited by these terms.

When a certain embodiment may be implemented differently, a specific process order may be performed differently from the described order. For example, two consecutively described processes may be performed substantially at the same time or in an order opposite to the described order.

In addition, the conductivity type or dopant type of a region, component or element may be defined as “P-type” or “N-type” according to the main carrier characteristics. However, this is only for convenience of description, and the technical spirit of the present disclosure is not limited to the above-mentioned examples. For example, “P-type” or “N-type” may be replaced hereinafter with the more general terms “first conductivity type” or “second conductivity type”. Here, the first conductivity type may refer to P type, and the second conductivity type may refer to N type.

It should be further understood that the terms “heavily doped” and “lightly doped” referring to or representing the doping concentration of an impurity region may mean the relative concentrations of dopant elements in the corresponding region(s), component(s) or elements.

Hereinafter, for convenience of description, the region where an emitter electrode and a body region therebelow are not electrically connected (i.e., the region where the body region is floating), is referred to as a “floating region A1”, and the region where the emitter electrode and the body region therebelow are electrically connected is referred to as an “active region A2”.

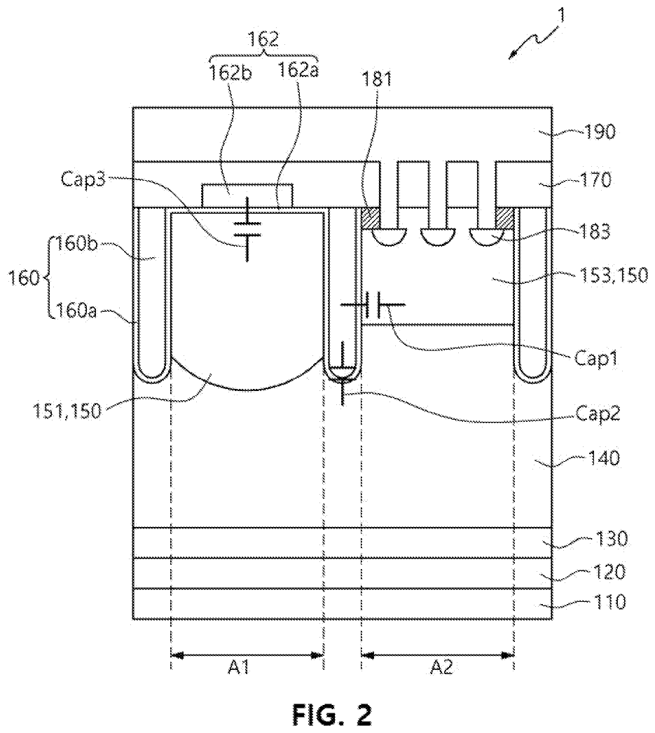

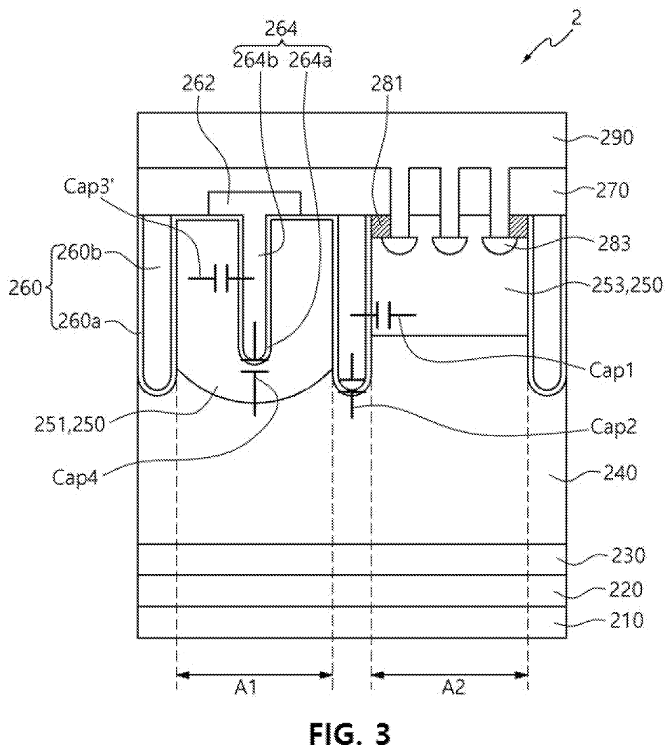

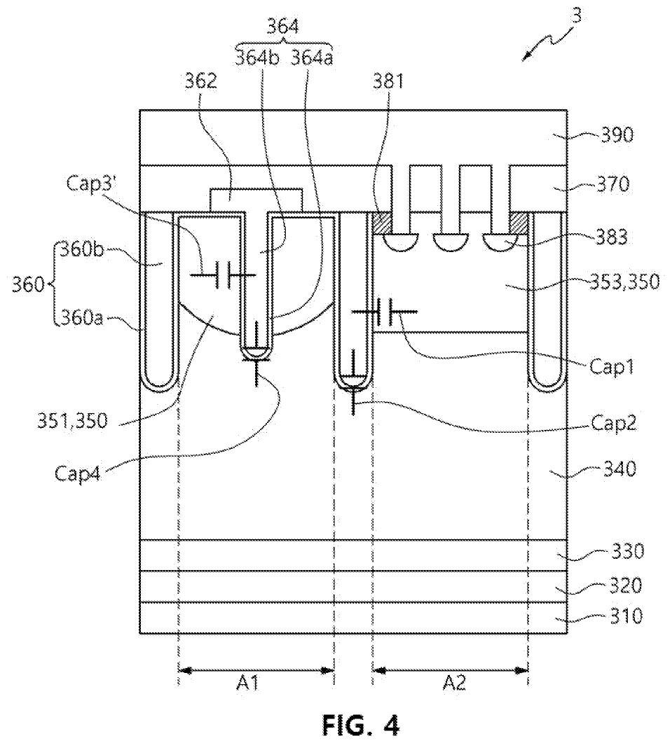

FIG. 2 is a cross-sectional view illustrating an exemplary insulated gate bipolar transistor 1 according to a first embodiment of the present disclosure; FIG. 3 is a cross-sectional view illustrating an insulated gate bipolar transistor 2 according to a second embodiment of the present disclosure; and FIG. 4 is a cross-sectional view illustrating an insulated gate bipolar transistor 3 according to a third embodiment of the present disclosure.

Hereinafter, an insulated gate bipolar transistor according to embodiments of the present disclosure will be described in detail with reference to the accompanying drawings. In the following, the exemplary insulated gate bipolar transistor 1 according to the first embodiment will be described as a reference, and aspects of the exemplary insulated gate bipolar transistors 2 and 3 according to the second and third embodiments that are different from those of the first embodiment will be primarily described.

Referring to FIG. 2, the present disclosure relates to an insulated gate bipolar transistor 1. More particularly, the present disclosure relates in one aspect to the insulated gate bipolar transistor 1, including a planar gate on a drift region or a first body region, which may be in the floating region A1. If desired or necessary, a second trench gate is additionally formed in the first body region to increase the input capacitance (Cies) of the insulated gate bipolar transistor and prevent self-turn-on.

The structures of the floating region A1 and the active region A2 will be described in detail.

A collector electrode 110 comprising, for example, a conductive metal alloy (e.g., an AlMoNiAu alloy) may have a collector or collector layer 120 (for example, a first conductivity type heavily doped semiconductor layer) thereon, or vice versa. A buffer layer 130 may be on the collector 120. The buffer layer 130 may comprise, for example, a second conductivity type heavily doped semiconductor (e.g., silicon) layer or substrate. A drift region 140 (for example, a second conductivity type semiconductor [e.g., silicon] layer or substrate), may be on the buffer layer 130. The drift region 140 may be lightly doped and may comprise, for example, a higher concentration of the second conductivity type dopant than the buffer layer 130. The collector electrode 110, the collector 120, the buffer layer 130, and the drift region 140 may be in and/or below both the floating region A1 and the active region A2.

One or more body regions 150 (for example, a first conductivity type semiconductor [e.g., silicon] layer), may be on or in the drift region 140 (e.g., at an uppermost surface thereof). For convenience of description, the body region 150 in the floating region A1 is referred to as a “first body region 151”, and the body region 150 in the active region A1 is referred to as a “second body region 153”. The first body region 151 may not be electrically connected to an emitter electrode 190, which will be described later, and the second body region 153 may be electrically connected to the emitter electrode 190. In this sense, the first body region 151 may be referred to as a floating body region. Also, referring to the first embodiment (see FIG. 2) and the second embodiment (see FIG. 3), the first body region 151, 251 may have a depth greater than that of the second body region 153, 253 in the drift region 140, 240. For example, a lowermost surface of the first body region 151, 251 may be deeper than a lowermost surface of the second body region 153, 253 in the drift region 140, 240.

Also, referring to the third embodiment (see FIG. 4), a first body region 351 may have substantially the same depth as a second body region 353. For example, a lowermost surface of the first body region 351 may be at substantially the same depth as a lowermost surface of the second body region 353 in the drift region 340.

A first trench gate 160 may be at a boundary between the first body region 151 and the second body region 153. It is preferable that the first trench gate 160 extends into the drift region 140 deeper than the second body region 153 so that a lowermost surface thereof is outside the second body region 153, but still substantially within the drift region 140. A plurality of first trench gates 160 may be horizontally apart from each other. Here, the body regions 151 and 153 may be in respective spaces between the first trench gates 160 (e.g., different sets of adjacent first trench gates 160).

Each of the first trench gates 160 may include a gate insulating layer 160a along an outer periphery thereof and a gate electrode 160b on an inner wall of and filling the gate insulating layer 160a. The gate insulating layer 160a may comprise, for example, a silicon dioxide layer, and the gate electrode 160b may comprise, for example, a polysilicon layer doped with second conductivity type impurities. As described above, the plurality of first trench gates 160 may be spaced apart from each other by a predetermined distance. The gate electrodes 160b on opposite sides of the second body region 153 may form a channel in the second body region 153 (e.g., when an activating voltage is applied thereto).

In addition, a planar gate 162 may be in the floating region A1 and on the drift region 140 or the first body region 151. The planar gate 162 may be between adjacent ones of the first trench gates 160 on opposite sides of the first body region 151. The planar gate 162 may include a gate insulating layer 162a on the first body region 151, and a gate electrode 162b on the gate insulating layer 162a. The planar gate 162 may comprise substantially the same material as the first trench gates 160.

Also, referring to the second embodiment (see FIG. 3), a second trench gate 264 may be below the planar gate 262 in the floating region A1. The second trench gate 264 may be in the first body region 251, and may have a lowermost surface within the first body region 251. That is, the second trench gate 264 may not pass through the first body region 251. Like the first trench gate 260, the second trench gate 264 may include a gate insulating layer 264a along an outer periphery thereof and a gate electrode 264b on an inner wall of and filling the gate insulating layer 264a. In addition, it is preferable that the second trench gate 264 has a narrower horizontal width than the first trench gate 260. As described above, the width of the second trench gate 264 is preferably relatively narrow, and the second trench gate 264 preferably has a shallower depth than the first trench gate 260 to minimize any increase in feedback capacitance (Cres) of the insulated gate bipolar transistor.

Also, referring to the third embodiment (see FIG. 4), the second trench gate 364 may be below the planar gate 362 in the floating region A1. Here, the second trench gate 364 may pass through the first body region 351. That is, a lowermost surface of the second trench gate 364 may extend into the drift region 340 below the first body region 351. Here, the vertical length or depth of the second trench gate 364 may be shorter, substantially the same as, or longer than that of the first trench gate 360. It is preferable that the second trench gate 364 has a narrower horizontal width than the first trench gate 360 and that the second trench gate 364 has a shallower depth than the first trench gate 360 to minimize any increase in the feedback capacitance (Cres).

Hereinbelow, the structure of an insulated gate bipolar transistor 9 according to the related art and the problems thereof, and exemplary insulated gate bipolar transistors 1, 2, and 3 according to the present disclosure to solve the problems will be described with reference to the accompanying drawings.

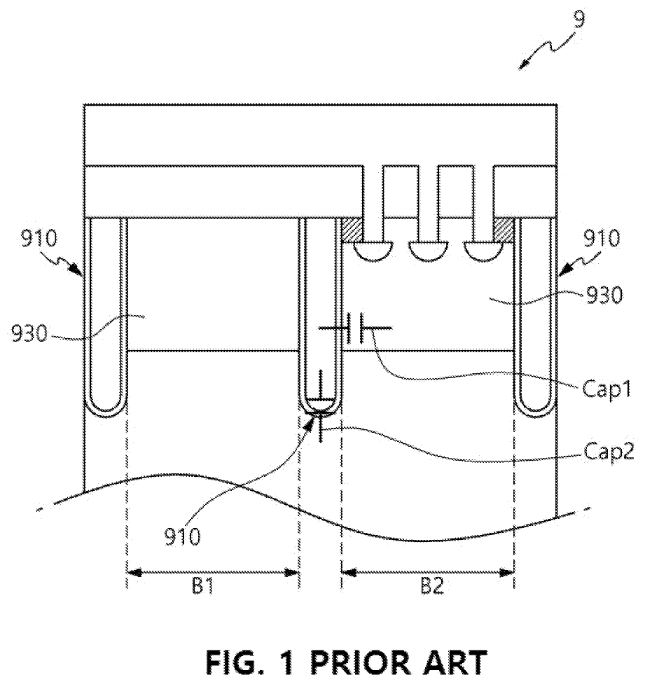

Referring to FIG. 1, in the insulated gate bipolar transistor 9 according to the related art, a trench gate 910 is at the boundary between a floating region B1 and an active region B2. In addition, a first conductivity type body region 930 is between adjacent ones of the trench gates 910. In general, when the insulated gate bipolar transistor 9 is implemented in an inverter, a pair of transistors 9 are designed to have different gate on/off times. In contrast, when the pair of transistors 9 are turned on simultaneously, there is a possibility that the devices may be damaged as a result of a short circuit.

In this case, if the input capacitance (Cies) of the transistors 9 is small, “self-turn-on” may occur in the devices due to gate noise. Thus, designing the input capacitance (Cies) to be large is advantageous in preventing self-turn-on. Here, the input capacitance (Cies) may be defined as the sum of a gate to collector parasitic capacitance (Cgc) and a gate to emitter parasitic capacitance (Cge). In the related-art transistor 9, the input capacitance (Cies) may be defined as the sum of a trench gate to emitter parasitic capacitance (Cge=Cap1) and a trench gate to collector parasitic capacitance (Cgc=Cap2) (Cies=Cap1+Cap2).

In order to prevent the conventional device self-turn-on, referring to FIG. 2, the transistor 1 according to the first embodiment of the present disclosure includes an additional planar gate 162 in the floating region A1. Thus, the gate to collector parasitic capacitance (Cgc) may be defined as the sum of a first trench gate to collector parasitic capacitance (Cap1) and a planar gate to collector parasitic capacitance (Cap3). Therefore, the input capacitance (Cies) may be defined as Cap1+Cap2+Cap3, and the transistor 1 according to the present disclosure can have a larger input capacitance (Cies) than the transistor 9 according to the related art.

Also, referring to FIG. 3, the exemplary transistor 2 according to the second embodiment is characterized by an additional second trench gate 264 in the floating region A1, together with the planar gate 262. Thus, compared to the transistor 9 according to the related art, a second trench gate to emitter parasitic capacitance (Cap3′) and a second trench gate to collector parasitic capacitance (Cap4) may be added. That is, the input capacitance (Cies) may be defined as Cap1+Cap2+Cap3′ +Cap4.

Referring to FIG. 4, this is equally applied to the third exemplary embodiment. Here, Cap4 may be smaller than Cap2. Since the planar gates 162, 262, 362 and the second trench gates 264, 364 described above are all only in the floating region A1, structural changes to the active region A1 are not made or required, and other characteristics of the device are not affected. In addition, as will be described in detail below, the second trench gates 264, 364 may be formed substantially simultaneously with the first trench gates 260, 360 (e.g., in the same process sequence and/or step[s]), and the planar gate 162, 262, 362 may also be formed at the same time as the first trench gate 160, 260, 360 in the process of forming the first trench gate 160, 260, 360, to minimize any deterioration in process efficiency.

Referring again to FIG. 2, an interlayer insulating layer 170 may be on the drift region 140 or the first body region 151 and the second body region 153. The interlayer insulating layer 170 may comprise, for example, a borophosphosilicate glass (BPSG), a phosphosilicate glass (PSG), a borosilicate glass (BSG), an undoped silicate glass (USG), etc., but is not limited thereto. The interlayer insulating layer 170 may be in both the floating region A1 and the active region A2, and may cover the planar gate 162. In addition, an emitter electrode 190 may be formed on the interlayer insulating layer 170. The emitter electrode 190 may be electrically connected to an emitter 181 and a body contact 183, which will be described later, and may include, for example, a conductive metal layer or a polysilicon layer. The emitter electrode 190 may include, for example, one or more contacts passing through the interlayer insulating layer 170 in the active region A2, physically connected to the body contact 183.

In addition, in the active region A2, an emitter 181 (for example, a second conductivity type heavily doped semiconductor [e.g., silicon] region), may be in the second body region 153 (e.g., at an uppermost surface thereof), for example, as a ring. The emitter 181 may have a first surface in contact with a side surface of the gate insulating layer 160a of the first trench gate 160, and a second surface in contact with the body contact 183 (comprising is a first conductivity type heavily doped impurity region), which will be described later. However, the scope of the present disclosure is not limited thereto.

An end or surface of one or more of the body contacts 183 may be in contact with or partially overlap the emitter 181 in the second body region 153. The body contacts 183 may comprise, for example, a first conductivity type impurity, and may have a higher concentration of dopant impurities than the second body region 153. With this structure, a hole or other carrier can easily move through the body contact 183, to provide an adequate switching speed (e.g., of the insulated gate bipolar transistor 1).

A detailed operation method of the transistor 1 according to the present disclosure will be described. When the gate 160 is turned on by applying a positive voltage difference between the emitter electrode 190 and the collector electrode 110 and applying a voltage higher than a threshold voltage to the gate electrode 160b, the channel reverses to or adopts a second conductivity type. Thereafter, electrons from the emitter electrode 190 move to the collector electrode 110 via the emitter 181, the channel, the drift region 140 and the collector 120. As a result, current flows from the collector electrode 110 to the emitter electrode 190.

When the gate is turned off, electrons and holes existing in the drift region 140 move to the collector electrode 110 and the emitter electrode 190, respectively. Here, the holes move to the emitter electrode 190 through the body contact 183.

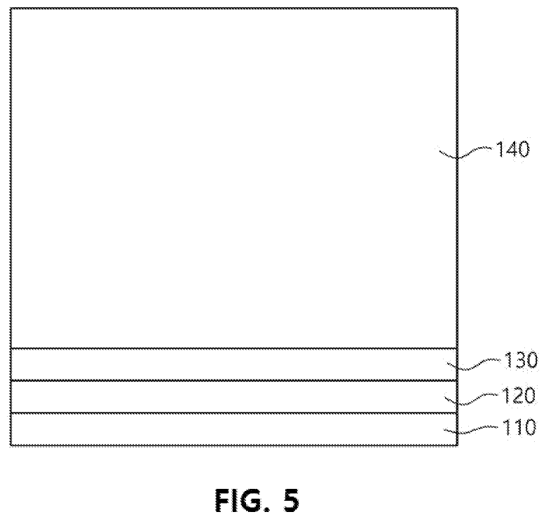

FIGS. 5 to 16 are cross-sectional views illustrating structures formed during an exemplary method of manufacturing an insulated gate bipolar transistor according to the present disclosure.

Hereinbelow, a method of manufacturing the insulated gate bipolar transistor 1 according to the first embodiment of the present disclosure will be described in detail with reference to the accompanying drawings. In methods of manufacturing the transistors 2 and 3 according to the second and third embodiments, only processes different from those of the method of manufacturing the transistor 1 according to the first embodiment will be described in detail.

Referring to FIG. 5, first, a buffer layer 130 may be formed (e.g., on a collector 120), or the collector 120 may be formed on the buffer layer 130. The collector or collector layer 120 may comprise a heavily doped first conductivity type semiconductor layer or substrate and the buffer layer 130 may comprise, for example, a second conductivity type heavily doped semiconductor layer or substrate. For example, the buffer layer 130 may be formed by epitaxial growth (e.g., of silicon) on a single-crystal silicon substrate including the collector or collector layer 120 on an outermost surface thereof.

After that, a drift region 140 may be formed on the buffer layer 130. The drift region 140 may comprise a second conductivity type lightly doped semiconductor layer. The drift region 140 may be formed by, for example, epitaxial growth (e.g., of silicon) on the buffer layer 130. As described above, the collector 120, the buffer layer 130, and the drift region 140 may be formed in both the floating region A1 and the active region A2 of the insulated gate bipolar transistor.

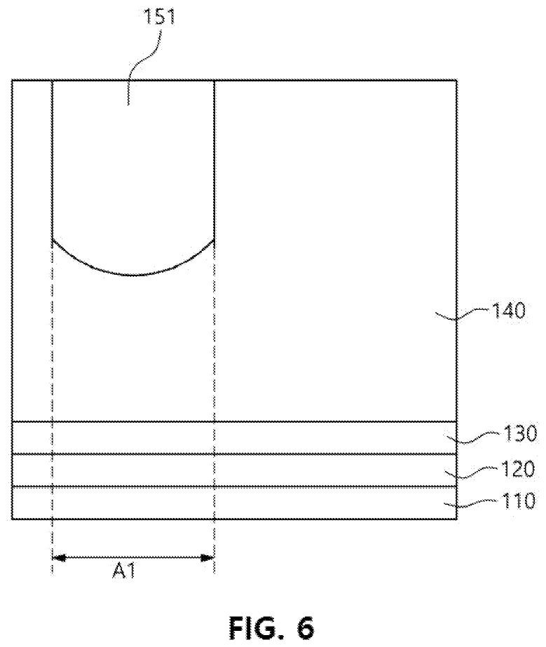

Then, referring to FIG. 6, a first body region 151 may be formed in the drift region 140, in the floating region A1. The first body region 151 may be formed by ion implantation through a mask pattern (not illustrated). The first body region 151 may comprise, for example, a first conductivity type impurity region in the drift region 140.

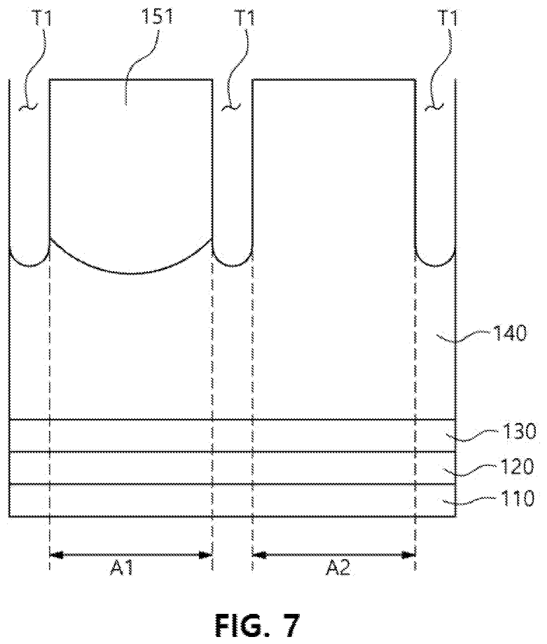

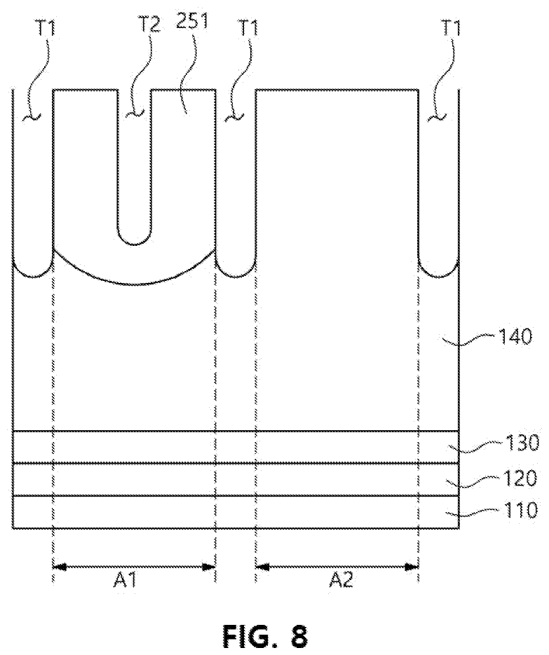

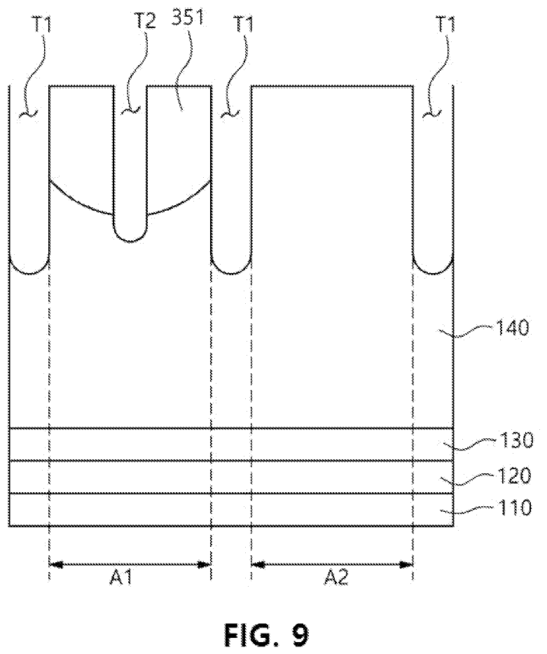

Then, referring to FIG. 7, a plurality of first trenches T1 for a plurality of first trench gates 160 may be formed. The first trenches T1 may be formed by etching the drift region 140 after forming a mask pattern (not illustrated) on the drift region 140 and the first body region 151. In the cases of the transistors 2 and 3 according to the second and third embodiments, a second trench T2 for a second trench gate 264 or 364 may be formed prior to, after, or at the same time as the first trenches T1 (see FIGS. 8 and 9). Referring to FIGS. 8 and 9, the second trench T2 may overlap a first body region 251 or 351 in the floating region A1. In addition, the second trench T2 preferably has a shallower depth than the first trenches T1, but the scope of the present disclosure is not limited thereto. When the second trench T2 has a sufficiently smaller width than the first trenches T1, the depth of the second trench T2 may naturally be shallower than that of the first trenches T1.

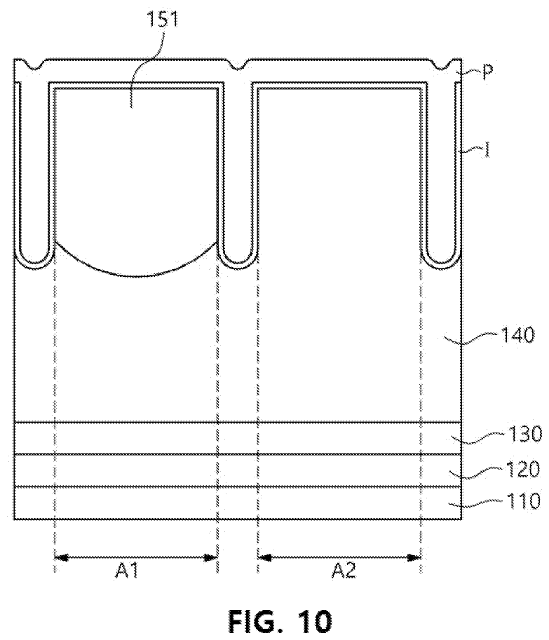

Then, referring to FIG. 10, after forming the first trenches T1 and, if desired or necessary, the second trench T2, an insulating layer I may be formed on the drift region 140 and in the first trenches T1 and the second trench T2 (e.g., by thermal growth or conformal blanket deposition of silicon dioxide). The insulating layer I may form a gate insulating layer 160a, 260a, 360a of each first trench gate 160, 260, 360 and a gate insulating layer 264a, 364a of the second trench gate 264, 364. In addition, the insulating layer I may form a gate insulating layer 162a of a planar gate 162.

After that, a polysilicon layer P may be formed on the insulating layer I. The polysilicon layer P may fill the first trenches T1 and, when present, the second trench T2, and be deposited on the insulating layer I on the drift region 140. By this process, the first trench gates 160, 260, 360 may be formed, and when the second trench T2 is present, the second trench gate 264, 364. Before forming the polysilicon layer P, the method may further comprise removing the insulating layer I in certain locations (e.g., on the drift region 140 in the active area A2).

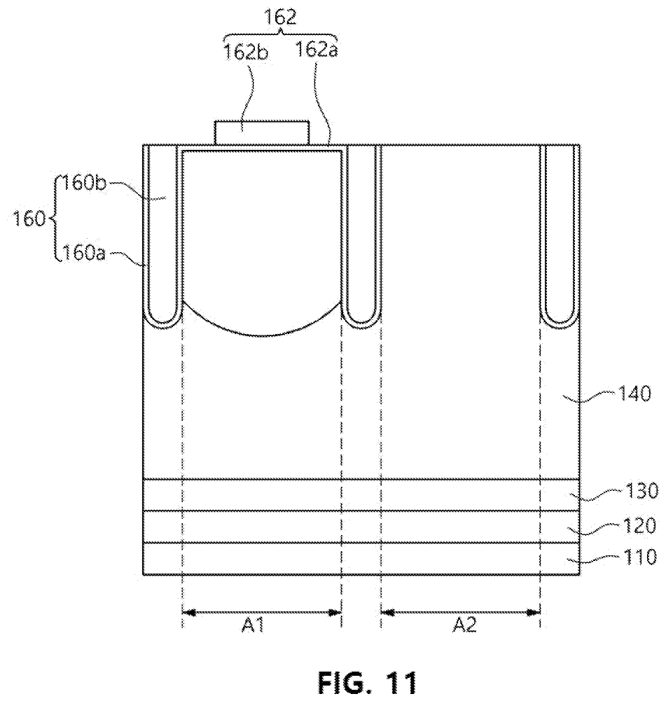

Then, referring to FIG. 11, the polysilicon layer P on the drift region 140 may be etched to form the planar gate 162. The planar gate 162 may be etched after forming a mask pattern (not illustrated) on the part of the polysilicon layer P forming the planar gate 162.

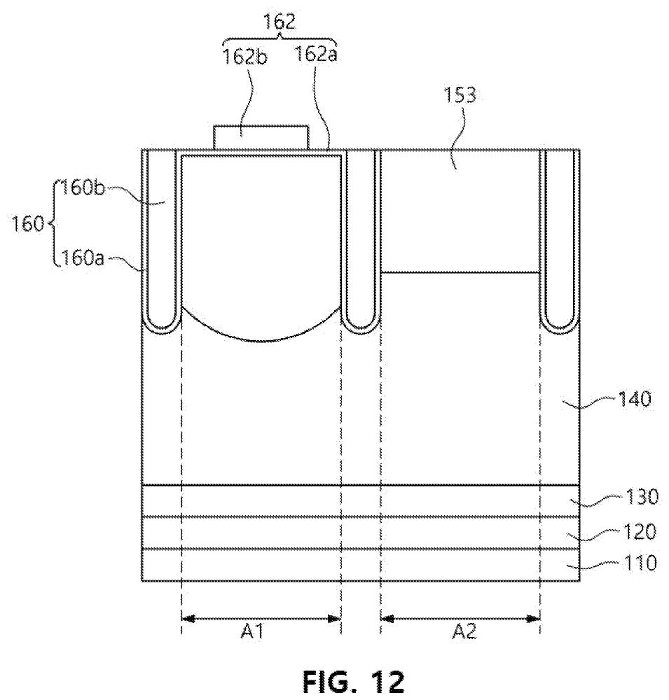

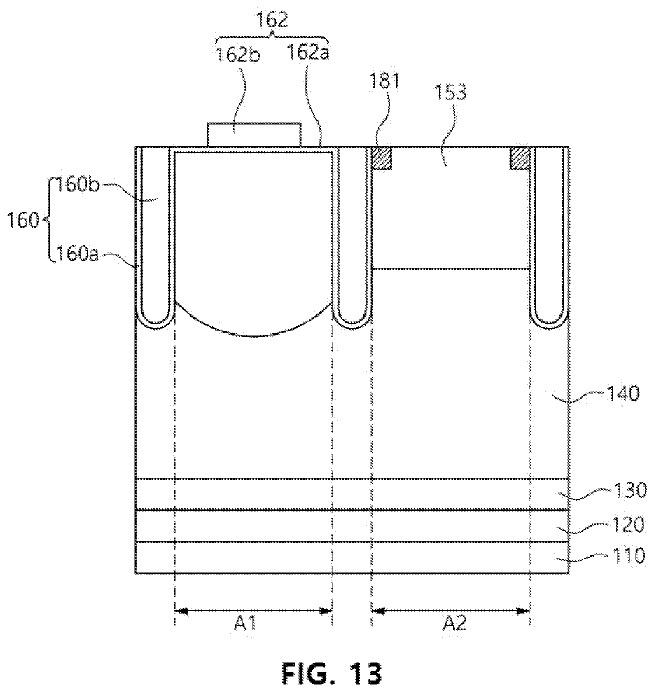

Then, referring to FIG. 12, a second body region 153 may be formed between adjacent first trench gates 160 in the active region A2. The second body region 153 may comprise, for example, a first conductivity type impurity region. The second body region 153 may be formed by ion implantation through a mask pattern (not illustrated). As described above, in the first and second embodiments, the second body region 153, 253 may have a shallower depth than the first body region 151, 251. Also, as in the third embodiment, a second body region 353 may have substantially the same depth as a first body region 351. After forming the second body region 153, referring to FIG. 13, an emitter 181 may be formed in the second body region 153. The emitter 181 may have, for example, a ring shape. The emitter 181 may be formed by implanting a high concentration of second conductivity type impurities through a mask pattern (not illustrated).

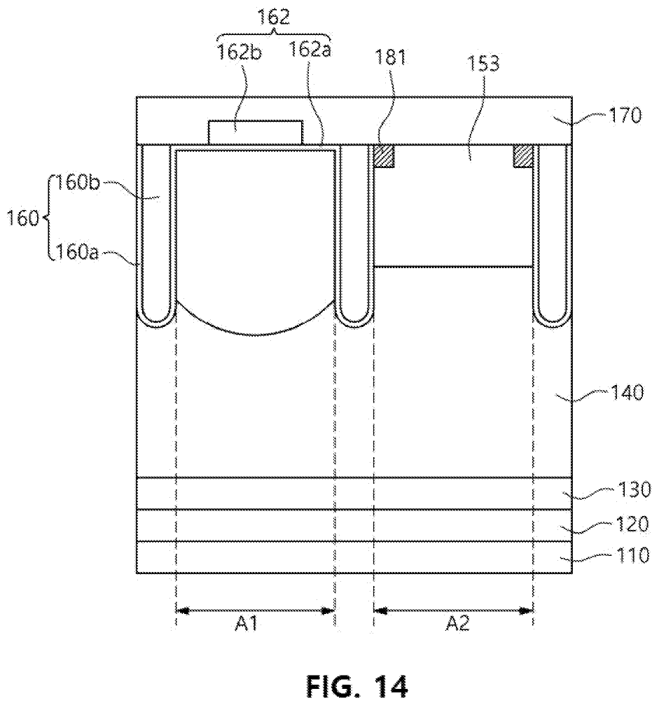

Then, referring to FIG. 14, an interlayer insulating layer 170 may be formed on the drift region 140 or on the first body region 151 and the second body region 153 by blanket deposition to cover the planar gate 162 and the first trench gates 160. As described above, the interlayer insulating layer 170 may comprise a borophosphosilicate glass (BPSG), a phosphosilicate glass (PSG), a borosilicate glass (BSG), an undoped silicate glass (USG), etc., but is not limited thereto. The interlayer insulating layer 170 may be planarized (e.g., by chemical mechanical polishing [CMP]) after deposition.

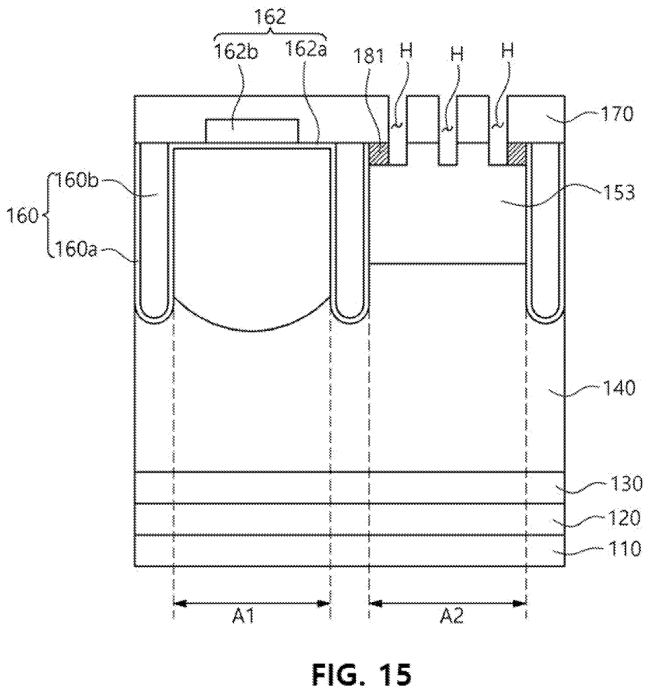

Then, referring to FIG. 15, contact holes H may be formed in the interlayer insulating layer 170 in the active region A2. The contact holes H may be formed by etching the interlayer insulating layer 170 using a mask pattern (not illustrated).

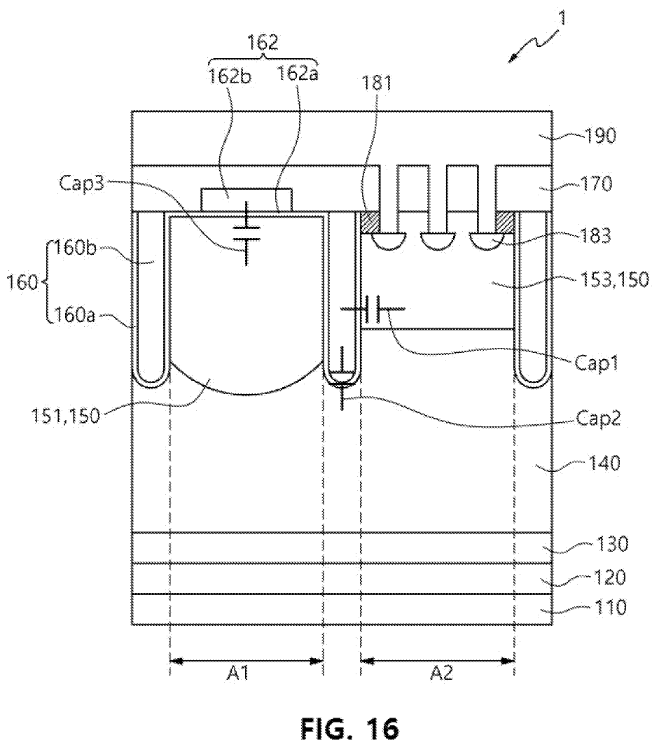

Then, referring to FIG. 16, a body contact 183 may be formed in each of the contact holes H by, for example, ion implantation through the contact holes H (e.g., using the interlayer insulating layer 170 as a hard mask). The body contacts 183 may comprise, for example, heavily doped first conductivity type impurity regions. After that, an emitter electrode 190 may be formed by forming a conductive layer on the interlayer insulating layer 170 and in the contact holes H.

Finally, a collector electrode 110 may be formed on a lower surface of the collector 120. As described above, the collector electrode 110 may comprise a conductive metal or metal alloy (e.g., AlMoNiAu), and be formed by blanket physical vapor deposition (e.g., sputtering using a target comprising the alloy) or electroplating (e.g., using a solution of one or more metal salts).

The foregoing detailed description may be merely examples of the present disclosure. Also, the inventive concept is explained by describing preferred embodiments and may be implemented using various combinations, modifications, and environments. That is, the inventive concept may be changed or modified without departing from the scope of the technical idea(s) and/or knowledge in the art. The foregoing embodiments are for illustrating various modes for implementing the technical idea of the present disclosure, and various modifications may be made therein according to specific applications and/or fields of use of the present disclosure. Therefore, the foregoing detailed description of the present disclosure is not intended to limit the inventive concept to the disclosed embodiments.

What is claimed is:

1. An insulated gate bipolar transistor comprising:
a collector electrode;
a collector on the collector electrode;
a drift region on the collector;
a plurality of first trench gates spaced apart from each other in the drift region;
a first body region between first adjacent ones of the first trench gates and in the drift region;
a second body region between second adjacent ones of the first trench gates and in the drift region; and
a planar gate between the first adjacent ones of the first trench gates and on the first body region.

2. The insulated gate bipolar transistor of claim 1, further comprising:
an interlayer insulating layer covering the planar gate, the first body region and the second body region; and
an emitter electrode on the interlayer insulating layer,
wherein the first body region floats.

3. The insulated gate bipolar transistor of claim 2, wherein a lowermost surface of the first body region is deeper in the drift region than a lowermost surface of the second body region.

4. The insulated gate bipolar transistor of claim 2, further comprising:
an emitter in the second body region; and
a body contact in the second body region,
wherein the emitter is electrically connected to the emitter electrode.

5. The insulated gate bipolar transistor of claim 2, wherein the planar gate comprises:
a gate insulating layer on the first body region; and
a gate electrode on the gate insulating layer.

6. The insulated gate bipolar transistor of claim 2, further comprising
a buffer layer on the collector.

7. An insulated gate bipolar transistor comprising:
a collector electrode;
a collector on the collector electrode;
a drift region on the collector;
a plurality of first trench gates spaced apart from each other in the drift region;
a first body region between adjacent ones of the first trench gates and in the drift region;
a second body region between different adjacent ones of the first trench gates and in the drift region;
a planar gate between the different adjacent ones of the first trench gates and on the first body region; and
a second trench gate in the first body region.

8. The insulated gate bipolar transistor of claim 7, wherein the second trench gate is connected to the planar gate.

9. The insulated gate bipolar transistor of claim 7, wherein the second trench gate has a lowermost surface in the first body region.

10. The insulated gate bipolar transistor of claim 7, wherein the second trench gate has a shallower depth than the first trench gates.

11. The insulated gate bipolar transistor of claim 10, wherein the second trench gate has a narrower width than the first trench gates.

12. The insulated gate bipolar transistor of claim 11, wherein the second trench gate comprises:
a gate insulating layer on an inner wall of a trench; and
a gate electrode on an inner wall of the gate insulating layer and filling the trench,
wherein the first body region floats.

13. An insulated gate bipolar transistor comprising:
a collector electrode;
a collector on the collector electrode;
a drift region on the collector;
a plurality of first trench gates spaced apart from each other in the drift region;
a floating first body region between first adjacent ones of the first trench gates and in the drift region, in a floating region of the insulated gate bipolar transistor;
a second body region between second adjacent ones of the first trench gates and in the drift region, in an active region of the insulated gate bipolar transistor;
a planar gate between the first adjacent ones of the first trench gates and on the first body region; and
a second trench gate spaced apart from the first adjacent ones of the first trench gates in the first body region, and having a lowermost surface deeper than a lowermost surface of the first body region.

14. The insulated gate bipolar transistor of claim 13, wherein the second trench gate has a narrower width and a smaller vertical length than the first trench gates.

15. The insulated gate bipolar transistor of claim 14, wherein first body region has a lowermost surface at substantially a same depth as a lowermost surface of the first body region.

16. A method of manufacturing an insulated gate bipolar transistor, the method comprising:
forming a drift region on a collector;
forming a first body region in a drift region in a floating region of the insulated gate bipolar transistor;
forming a plurality of first trench gates spaced apart from each other in the drift region;
forming a planar gate on the first body region;
forming a second body region in the drift region in an active region of the insulated gate bipolar transistor;
forming an emitter in the second body region;
forming an interlayer insulating layer on the first body region and the second body region and covering the planar gate; and
forming an emitter electrode on the interlayer insulating layer.

17. The method of claim 16, wherein forming the plurality of first trench gates comprises:
forming a plurality of first trenches having a first depth in the drift region;
forming an insulating layer in the first trenches and on the first body region; and
forming a polysilicon layer on the insulating layer to form the first trench gates.

18. The method of claim 17, further comprising forming a second trench having a second depth between a pair of the first trenches and in the first body region, forming the insulating layer in the second trench, and forming the polysilicon layer in the second trench, wherein the second depth is shallower than the first depth.

19. The method of claim 17, wherein forming the emitter electrode on the interlayer insulating layer comprises:
forming a contact hole in the interlayer insulating layer in the active region;
forming a body contact in the second body region through the contact hole; and
forming a conductive layer in the contact hole and on the interlayer insulating layer.

20. The method of claim 17, wherein forming the planar gate comprises etching the polysilicon layer on the insulating layer.
